(19) United States
(12) Patent Application Publication
(10) Pub. No.: US 2024/0222001 A1
(43) Pub. Date: Jul. 4, 2024

(54) COIL COMPONENT

(71) Applicant: SAMSUNG ELECTRO-MECHANICS CO., LTD., Suwon-si (KR)

(72) Inventors: Ye Ji JUNG, Suwon-si (KR); Jae Hun KIM, Suwon-si (KR); Ju Hwan YANG, Suwon-si (KR); Boum Seock KIM, Suwon-si (KR)

(73) Assignee: SAMSUNG ELECTRO-MECHANICS CO., LTD., Suwon-si (KR)

(21) Appl. No.: 18/513,878

(22) Filed: Nov. 20, 2023

(30) Foreign Application Priority Data
Jan. 3, 2023 (KR) 10-2023-0000806

(51) Int. Cl. H01F 27/32; H01F 5/06

(52) U.S. Cl. CPC H01F 27/324; H01F 5/06

(57) ABSTRACT

A coil component includes a body including a first surface and a second surface opposing in a first direction, a third surface and a fourth surface disposed between the first surface and the second surface and opposing in the second direction, and a fifth surface and a sixth surface disposed between the first surface and the second surface and opposing in the third direction; a coil disposed in the body and forming a plurality of turns; an insulating wall surrounding a side surface of the coil; an insulating layer covering the coil in the third direction; and an external electrode connected to the coil. A length of the insulating layer in the third direction is a1, a length of an outermost side wall in the first direction, disposed on an outermost side of the insulating wall in the first direction, is b, and 2.11%<a1/b<18.01% is satisfied.

### CROSS-REFERENCE TO RELATED APPLICATION (S)

This application claims benefit of priority to Korean Patent Application No. 10-2023-0000806 filed on Jan. 3, 2023 in the Korean Intellectual Property Office, the disclosure of which is incorporated herein by reference in its entirety.

### BACKGROUND

### 1. Technical Field

The present disclosure relates to a coil component.

### 2. Description of the Related Art

With the reduction of a size and a thickness of an electronic device such as a digital TV, a mobile phone, and a laptop, a coil component applied to the electronic device may also need to have a reduced size and thickness. To meet these demands, research and development of various wound-type coil components or thin film-type coil components have been conducted.

A major issue due to reduction of a size and thickness of coil component may be to implement properties equivalent to those of a generally used coil component despite the reduction. To satisfy the demands, it may be necessary to increase a ratio of magnetic material in a core filled with a magnetic material, but there may be a limitation in increasing the ratio due to strength of an inductor body and changes in frequency properties according to insulation.

In a miniaturized thin-film power inductor, the possibility of short circuit may increase as a distance between an external electrode and a coil decreases. To address this issue, when the insulating layer on a surface of a coil is configured to have an increased thickness, the amount of magnetic material in the body may be reduced, which may also lead to a decrease in properties.

### SUMMARY

An aspect of the present disclosure is to provide a coil component having improved electrical properties. Another aspect of the present disclosure is to provide a coil component which may be advantageous for miniaturization and may have excellent properties by securing a core having a sufficient size.

According to an aspect of the present disclosure, a coil component includes a body including a first surface and a second surface opposing each other in a first direction, a third surface and a fourth surface opposing each other in a second direction and disposed between the first surface and the second surface, and a fifth surface and a sixth surface opposing each other in a third direction and disposed between the first surface and the second surface; a coil disposed in the body and including a plurality of turns; an insulating wall surrounding a side surface of the coil and comprising an outermost side wall disposed on an outermost side of the insulating wall in the first direction; an insulating layer covering the coil in the third direction; and an external electrode connected to the coil, wherein, when a length of the insulating layer in the third direction is defined as a1 and a length of the outermost side wall in the first direction is defined as b, 2.11%<a1/b<18.01% is satisfied.

When a length, in the first direction, of an internal side wall disposed inwardly of the outermost side wall is defined as a2, a2 and b may satisfy 1.54%<a2/b<11.3%.

a1 and a2 may satisfy a1>a2.

a1 and a2 may satisfy a1≤a2.

The insulating wall may include a plurality of internal side walls, and a2 may be an average of lengths of the plurality of internal side walls in the first direction.

a1 may be 3 μm or more.

b may be the length of the outermost side wall in a cross-section of the body in the first direction and third direction, including a central portion in the second direction.

a1 may be a length of the insulating layer in a cross-section of the body in the first direction and third direction, including a central portion in the second direction.

The coil component may further include a support member disposed in the body and supporting the coil.

A length of the support member in the third direction may be 5 μm or more and 40 μm or less.

The coil may include a first coil disposed on one surface of the support member and having an end extending to the first surface of the body, and the insulating wall may include a first insulating wall disposed on the one surface of the support member and having a first outermost side wall extending to a second surface of the body.

The coil may further include a second coil disposed on the other surface of the support member and having an end extending to a second surface of the body, and the insulating wall may further include a second insulating wall disposed on the other surface of the support member and having a second outermost side wall extending to the first surface of the body.

The insulating layer may cover the insulating wall in the third direction.

The insulating wall may include a photosensitive insulating resin.

An edge of the coil facing the insulating layer may be flushed with an edge of the insulating wall facing the insulating layer.

The support member may include a photosensitive insulating resin.

### BRIEF DESCRIPTION OF DRAWINGS

The above and other aspects, features, and advantages of the present disclosure will be more clearly understood from the following detailed description, taken in conjunction with the accompanying lead-outs, in which:

FIG. 1 is a perspective diagram illustrating a coil component according to an embodiment of the present disclosure;

FIGS. 2 and 3 are cross-sectional diagrams illustrating the coil component illustrated in FIG. 1;

FIGS. 4 and 5 are diagrams illustrating a form of an insulating wall in the coil component illustrated in FIG. 1; and

FIGS. 6 and 7 are diagrams illustrating an example in which a coil is disposed in an opening of an insulating wall in the coil component in FIG. 1.

### DETAILED DESCRIPTION

Hereinafter, embodiments of the present disclosure will be described as follows with reference to the attached drawings.

The present disclosure may, however, be exemplified in many different forms and should not be construed as being limited to the specific embodiments set forth herein. Rather, these embodiments are provided such that this disclosure will be thorough and complete, and will fully convey the scope of the disclosure to those skilled in the art. Accordingly, shapes and sizes of the elements in the drawings may be exaggerated for clarity of description. Also, elements having the same function in the scope of the same concept represented in the drawing of each embodiment will be described using the same reference numeral.

Various types of electronic components may be used in electronic devices, and various types of coil components may be appropriately used between these electronic components for the purpose of removing noise. That is, in an electronic device, a coil component may be used as a power inductor, a HF inductor, a general bead, a GHz bead, a common mode filter, or the like.

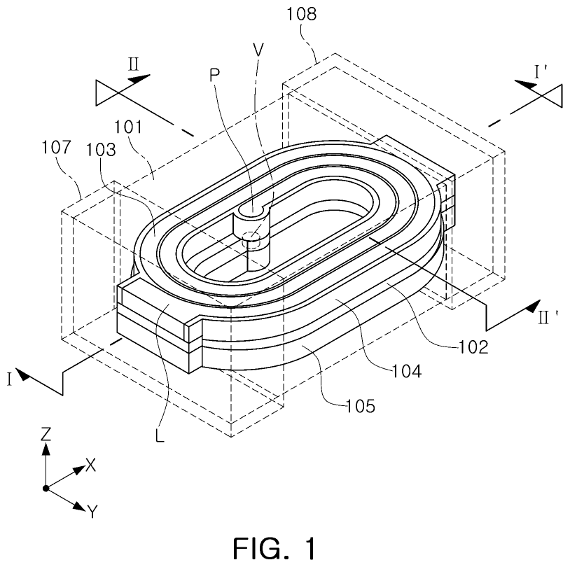

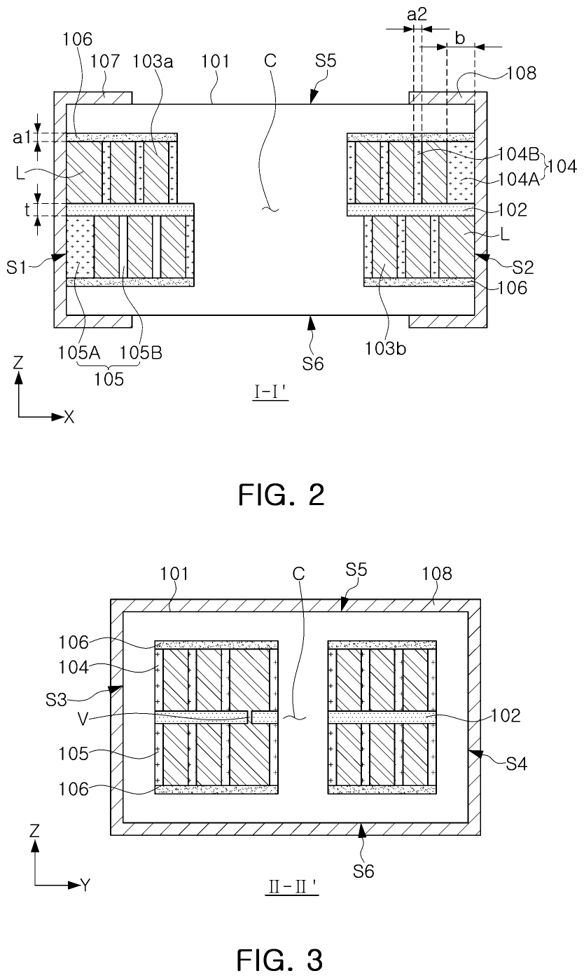

FIG. 1 is a perspective diagram illustrating a coil component according to an embodiment. FIGS. 2 and 3 are cross-sectional diagrams illustrating the coil component illustrated in FIG. 1.

Referring to FIGS. 1 to 3, a coil component 100 in an embodiment may include a body 101, a support member 102, a coil 103, insulating walls 104 and 105, an insulating layer 106, and external electrodes 107 and 108 as main components. Here, a length a1 of the insulating layer 106 in the third direction (Z-direction) and a length b of the outermost side walls 104A and 105A of the insulating walls 104 and 105 in the first direction (X-direction) may satisfy 2.11%<a1/b<18.01%, which corresponds to the condition calculated considering reliability and inductance properties such as short circuit defects, which will be described later. Hereinafter, main elements included in the coil component 100 in an embodiment will be described.

The body 101 may form an exterior of the coil component 100, and the coil 103 and the support member 102 may be disposed therein. As illustrated, the body 101 may be formed in the shape of a hexahedral shape. The body 101 may include a first surface S1 and a second surface S2 opposing each other in the first direction (X-direction), a third surface S3 and a fourth surface S4 located between the first surface S1 and the second surface S2 and opposing each other in the second direction (Y-direction), and a fifth surface S5 and a sixth surface S6 located between the first surface S1 and the second surface S2 and opposing each other in third direction (Z-direction). In this case, the first to third directions (X-Z directions) may be perpendicular to each other. As an example, in the body 101, the coil component 100 according to an embodiment in which the external electrodes 107 and 108 are formed may be configured to have a length of 2.5 mm, a width of 2.0 mm and a thickness of 1.0 mm, or a length of 2.0 mm, a width of 1.2 mm and a thickness of 0.65 mm, or a length of 1.6 mm, a width of 0.8 mm and a thickness of 0.8 mm, or a length of 1.0 mm, a width of 0.5 mm and a thickness of 0.5 mm, or a length of 0.8 mm, a width of 0.4 mm and a thickness of 0.65 mm, but an embodiment thereof is not limited thereto. Since the above-described numerical values are merely design values not reflecting process errors, the range recognized as a process error may belong to an embodiment.

The length of the coil component 100 in the first direction (X-direction) may be a maximum value of each dimension of a plurality of line segments connecting the two outermost boundary lines opposing each other in the first direction (X-direction) of the coil component 100 illustrated in the cross-sectional image and parallel to the first direction (X-direction) with respect to an optical microscope or scanning electron microscope (SEM) image of a cross-section in the first direction (X-direction) -third direction (Z-direction) in central portion of coil component 100 in the second direction (Y-direction), a minimum value of dimensions of each of a plurality of line segments connecting the two outermost boundary lines opposing each other in the first direction (X-direction) of the coil component 100 illustrated in the cross-sectional image and parallel to the first direction (X-direction), or an arithmetic mean of at least three of dimensions of each of a plurality of line segments connecting the two outermost boundary lines opposing each other in the first direction (X-direction) of the coil component 100 illustrated in the cross-sectional image and parallel to the first direction (X-direction). Here, the plurality of line segments parallel to the first direction (X-direction) may be equally spaced apart from each other in the third direction (Z-direction), but an embodiment thereof is not limited thereto.

The length of the coil component 100 in the second direction (Y-direction) may be a maximum value of each dimension of a plurality of line segments connecting the two outermost boundary lines opposing each other in the second direction (Y-direction) of the coil component 100 illustrated in the cross-sectional image and parallel to the second direction (Y-direction) with respect to an optical microscope or scanning electron microscope (SEM) image of a cross-section in the first direction (X-direction)-second direction (Y-direction) in a central portion of coil component 100 in the third direction (Z-direction), a maximum value of each dimension of a plurality of line segments connecting the two outermost boundary lines opposing each other in the second direction (Y-direction) of the coil component 100 illustrated in the cross-sectional image and parallel to the second direction (Y-direction), a minimum value of each dimension of a plurality of line segments parallel to the second direction (Y-direction) connecting the two outermost boundary lines opposing each other in the second direction (Y-direction) of the coil component 100 illustrated in the cross-sectional image, or an arithmetic mean of at least three of dimensions of each of a plurality of line segments connecting the two outermost boundary lines opposing each other in the second direction (Y-direction) of the coil component 100 illustrated in the cross-sectional image and parallel to the second direction (Y-direction). Here, the plurality of line segments parallel to the second direction (Y-direction) may be equally spaced apart from each other in the first direction (X-direction), but an embodiment thereof is not limited thereto.

The length in the third direction (Z-direction) of the coil component 100 described above may be a maximum value of dimensions of each of the plurality of line segments connecting the two outermost boundary lines opposing each other in the third direction (Z-direction) of the coil component 100 illustrated in the cross-sectional image and parallel to the third direction (Z-direction) with respect to an optical microscope or scanning electron microscope (SEM) image of a cross-section in the first direction (X-direction)-third direction (Z-direction) in a central portion of coil component 100 in the second direction (Y-direction), a minimum value among dimensions of each of the plurality of line segments connecting the two outermost boundary lines opposing each other in the third direction (Z-direction) of the coil component 100 illustrated in the cross-sectional image and parallel to the third direction (Z-direction), or an arithmetic mean of at least three of dimensions of each of a plurality of line segments connecting the two outermost boundary lines opposing each other in the third direction (Z-direction) of the coil component 100 illustrated in the cross-sectional image and parallel to the third direction (Z-direction). Here, the plurality of line segments parallel to the third direction (Z-direction) may be equally spaced apart from each other in the first direction (X-direction), but an embodiment thereof is not limited thereto.

Each of the lengths of the first to third directions of the coil component 100 may be measured by a micrometer measurement method. The micrometer measurement method may be to measure by setting a zero point with a micrometer with Gage R&R (repeatability and reproducibility), inserting a coil component 100 according to an embodiment between tips of the micrometer, and turning the measuring lever of the micrometer. In measuring the length of the coil component 100 by the micrometer measurement method, the length of the coil component 100 may refer to a value measured once or may refer to an arithmetic average of values measured multiple times.

The body 101 may include an insulating resin and a magnetic material, and may include a core C penetrating through the support member 102 and coil 103. Specifically, the body 101 may be formed by laminating one or more magnetic composite sheets in which a magnetic material is dispersed in an insulating resin. The magnetic material may be ferrite or metallic magnetic powder. Ferrite may be at least one of, for example, spinel-type ferrite such as Mg—Zn-based ferrite, Mn—Zn-based ferrite, Mn—Mg-based ferrite, Cu—Zn-based ferrite, Mg—Mn—Sr-based ferrite, Ni—Zn-based ferrite, hexagonal ferrites such as Ba—Zn-based ferrite, Ba—Mg-based ferrite, Ba—Ni-based ferrite, Ba—Co-based ferrite, Ba—Ni—Co-based ferrite, garnet-type ferrites such as Y-based ferrite, and Li-based ferrites. Metal magnetic powder may include one or more selected from a group consisting of iron (Fe), silicon (Si), chromium (Cr), cobalt (Co), molybdenum (Mo), aluminum (Al), niobium (Nb), copper (Cu) and nickel (Ni). For example, the magnetic metal powder may be at least one of pure iron powder, Fe—Si alloy powder, Fe—Si—Al alloy powder, Fe—Ni alloy powder, Fe—Ni—Mo alloy powder, Fe—Ni—Mo—Cu alloy powder, Fe—Co alloy powder, Fe—Ni—Co alloy powder, Fe—Cr alloy powder, Fe—Cr—Si alloy powder, Fe—Si—Cu—Nb alloy powder, Fe—Ni—Cr-based alloy powder and Fe—Cr—Al alloy powder. The metal magnetic powder may be amorphous or crystalline. For example, the magnetic metal powder may be a Fe—Si—B—Cr amorphous alloy powder, but an embodiment thereof is not limited thereto. Each of ferrite and metal magnetic powder particles may have an average diameter of about 0.1 μm to about 30 μm, but an embodiment thereof is not limited thereto. The body 110 may include two or more types of magnetic materials dispersed in resin. Here, the notion that the magnetic materials are of different types may indicate the magnetic materials dispersed in the resin may be distinguished from each other by one of an average diameter, a composition, crystallinity and a shape. Meanwhile, hereinafter, the magnetic material may be a metal magnetic powder, but an embodiment thereof is not limited only to the body 110 having a structure in which the metal magnetic powder is dispersed in an insulating resin. The insulating resin may include epoxy, polyimide, and liquid crystal polymer alone or in combination, but an embodiment thereof is not limited thereto.

The support member 120 may be disposed in the body 110 and may support the coil 103. The support member 102 is not an essential component in an embodiment and may not be provided alternatively. The thickness of the support member 102, that is, the length t in the third direction (Z-direction) may be 5 μm or more in consideration of the support function, and the thickness may be configured to be less than 40 μm on the miniaturized side surface of the coil component 100.

As a specific example, the support member 120 may be formed of an insulating material including a thermosetting insulating resin such as epoxy resin, a thermoplastic insulating resin such as polyimide, or a photosensitive insulating resin, or an insulating material impregnated with reinforcing materials such as glass fibers or inorganic fillers in these insulating resins. More specifically, the support member 120 may be formed of an insulating material such as prepreg, Ajinomoto build-up film (ABF), FR-4, bismaleimide triazine (BT) resin, photoimagable dielectric (PID), but an embodiment thereof is not limited thereto. As an inorganic filler, at least one selected from a group consisting of silica (silicon dioxide, SiO₂), alumina (aluminum oxide, Al₂O₃), silicon carbide (SiC), barium sulfate (BaSO₄), talc, mud, mica powder, aluminum hydroxide (Al(OH)₃), hydroxide magnesium (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃) and calcium zirconate (CaZrO₃) may be used. When the support member 120 is formed of an insulating material including a reinforcing material, the support member 120 may provide improved rigidity. When the support member 120 is formed of an insulating material not including glass fiber, it may be advantageous to reduce a thickness of the coil component 100 according to an embodiment. Also, with respect to the body 110 of the same size, the volume occupied by the coil 103 and/or the magnetic metal powder may be increased, such that component properties may be improved. When the support member 102 is formed of an insulating material including a photosensitive insulating resin, the number of processes for forming the coil 103 may be reduced, which is advantageous in reducing production and costs, the conductive via V may be formed finely.

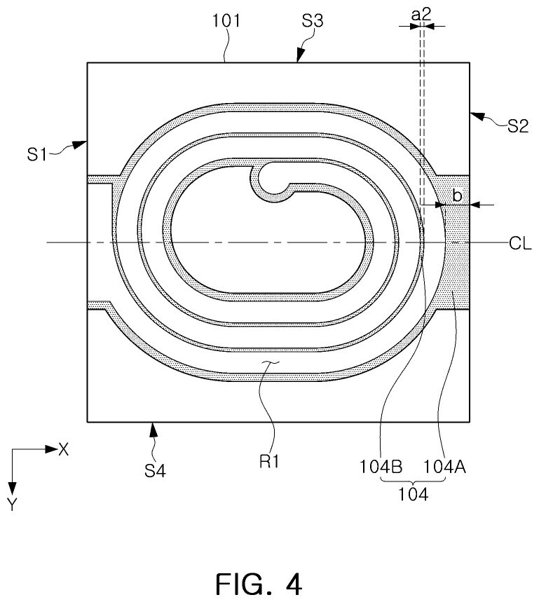

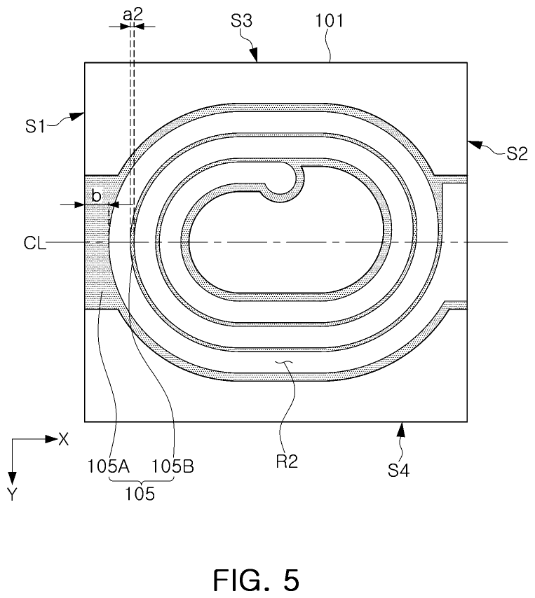

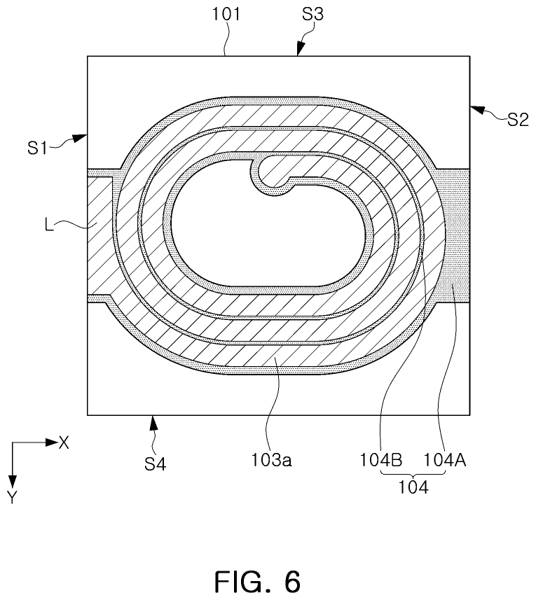

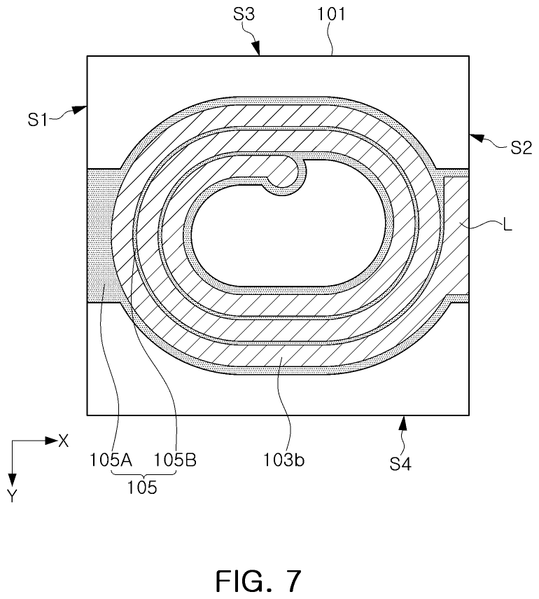

The insulating walls 104 and 105 and the coil 103 will be described in greater detail with reference to FIGS. 4 to 7. FIGS. 4 and 5 are diagrams illustrating a form of an insulating wall in the coil component illustrated in FIG. 1. FIGS. 6 and 7 are diagrams illustrating an example in which a coil is disposed in an opening of an insulating wall in the coil component in FIG. 1.

The insulating walls 104 and 105 may be disposed in the body 101 and may surround a side surface of the coil 103. To this end, as illustrated, the insulating walls 104 and 105 may have openings R1 and R2, respectively. The insulating walls 104 and 105 may function as masks in a process for forming the coil 103 (e.g., a plating process), and to this end, the openings R1 and R2 may have a coil shape. The insulating walls 104 and 105 may include the first insulating wall 104 having a first outermost side wall 104A disposed on one surface (upper surface relative to the surface) of the support member 102 and extending to the second surface S2 of the body 101, and the second insulating wall 105 having a second outermost side wall 105A disposed on the first insulating wall 104 and the other surface (lower surface with respect to the surface) of the support member 102 and extending to the first surface S1 of the body 101. Also, the insulating walls 104 and 105 may include internal side walls 104B and 105B disposed adjacent to the outermost side walls 104A and 105A in the first direction (X-direction). In this case, a plurality of the internal side walls 104B and 105B may be provided. As illustrated, the length b of the outermost side walls 104A and 105A in the first direction may be configured to be longer than the length a1 of the internal side walls 104B and 105B in the first direction, thereby reducing the possibility of a short circuit between the coil 103 and the external electrodes 107 and 108.

The insulating walls 104 and 105 may include thermoplastic resins such as polystyrene, vinyl acetate, polyester, polyethylene, polypropylene, polyamide, rubber, and acrylic, thermosetting resins such as phenolic, epoxy, urethane, melamine, alkyd, photosensitive resin, parylene, and SiOx or SiNx. As an example, the insulating walls 104 and 105 may include a photosensitive insulating resin. That is, the insulating walls 104 and 105 may be formed of a photosensitive material which may be a combination of one photoacid generator (PAG) and several epoxy resins, and one or more types of epoxy may be used. When the insulating walls 104 and 105 include photosensitive insulating resin, openings R1 and R2 may be formed by a photolithography method.

The coil 103 may form a plurality of turns. Also, the coil 103 may be disposed in the openings R1 and R2 of the insulating walls 104 and 105 and may be supported by the support member 102. Specifically, the coil 103 may include first and second coils 103a and 103b. The first coil 103a may have an end L disposed on one surface of the support member 102 and extending to first surface S1 of body 101, and the second coil 103b may have an end L disposed on the other surface of the support member 102 and extending to the second surface S2 of the body 101. The lead-out portion L of the first and second coils 103a and 103b may be disposed in the outermost portion of each of the first and second coils 103a and 103b and may provide a connection path with the external electrodes 107 and 108 and may be integrally formed with the coil 103. In this case, as illustrated in the diagram, for connection with the external electrodes 107 and 108, the end L may be configured to have a greater width than that of the coil 103, where the width may refer to the width in the Y-direction with reference to FIG. 1. The first and second coils 103a and 103b may include a pad P, and may be connected to each other by a conductive via V penetrating through the support member 102.

The coil 103 may include at least one conductive layer. Specifically, the first and second coils 103 may be formed through a plating process, and in this case, the coil 103 may include a seed layer and an electroplating layer. Here, the electrolytic plating layer may have a single-layer structure or a multilayer structure. The electroplating layer having a multilayer structure may be formed in a conformal film structure in which another electroplating layer is formed along the surface of one of the electroplating layers, or may be formed in a shape in which another electroplating layer is laminated only on one surface of one of the electroplating layers. The seed layer may be formed by a vapor deposition method such as electroless plating or sputtering. The coil 103 may be formed of a conductive material such as copper (Cu), aluminum (Al), silver (Ag), tin (Sn), gold (Au), nickel (Ni), lead (Pb), titanium (Ti), chromium (Cr) or an alloy thereof, but an embodiment thereof is not limited thereto.

The insulating layer 106 may be disposed to cover the coil 103 in a third direction (Z-direction), and may also cover the insulating walls 104 and 105 in a third direction (Z-direction) in addition to the coil 103. The insulating layer 106 may include the coil 103 along with the insulating walls 104 and 105 embedded therein such that the coil 103 may be electrically insulated from the body 101. The insulating layer 106 may include at least one selected from a group consisting of an epoxy based resin, a polyimide resin, and a liquid crystal crystalline polymer (LCP) resin, and may also be formed of a metal oxide. As an example, the insulating layer 106 may be formed by stacking an insulating film for forming a cover insulating layer such as dry film (DF). Alternatively, the insulating layer 106 may be formed by vapor deposition or sputtering. Also, the insulating layer 106 may be formed by applying a liquid insulating material such as spin coating.

The external electrodes 107 and 108 may be spaced apart from each other in the body 101 and may be connected to the coil 103, and specifically, the external electrodes 107 and 108 may include first and second external electrodes 107 and 108 connected to the first and second coils 103a and 103b, respectively. The first external electrode 107 may be disposed on the first surface S1 of the body 101 and may be connected to the end L of the first coil 103a exposed to the first surface S1 of the body 101, and the second external electrode 108 may be disposed on the second surface S2 of the body 101, and may be connected to the end L of the second coil 103b exposed to the second surface S2 of the body 101. As illustrated, the first external electrode 107 may be disposed on the first surface S1 of the body 101 and may extend to the third surface to the sixth surface S3-S6 of the body 101. The second external electrode 107 may be disposed on the second surface S2 of the body 101 and may extend to the third surface to the sixth surface S3-S6 of the body 101. Also, each of the first and second external electrodes 107 and 108 disposed on the first surface S1 and the second surface S2 of the body 101 may extend only to the sixth surface S6 of the body 101.

The external electrodes 107 and 108 may be formed by a vapor deposition method such as sputtering and/or a plating method, but an embodiment thereof is not limited thereto. The external electrode 107 and 108 may be formed of a conductive material such as copper (Cu), aluminum (Al), silver (Ag), tin (Sn), gold (Au), nickel (Ni), lead (Pb), chromium (Cr), titanium (Ti), or alloys thereof, but an embodiment thereof is not limited thereto. The external electrodes 107 and 108 may be formed in a single layer multilayer structure. For example, the structure or a external electrodes 107 and 108 may include a first conductive layer including copper (Cu), a second conductive layer disposed on the first conductive layer and including nickel (Ni), and a third conductive layer disposed on the second conductive layer and including tin (Sn). At least one of the second conductive layer and the third conductive layer may be formed to cover the first conductive layer, but an embodiment thereof is not limited thereto. The first conductive layer may be configured as a plating layer or a conductive resin layer formed by applying and curing a conductive resin including conductive powder and resin including at least one of copper (Cu) and silver (Ag). The second and third conductive layer may be configured as a plating layer, but an embodiment thereof is not limited thereto.

In an embodiment, the length b of the outermost side walls 104A and 105A disposed on the outermost side of the insulating walls 104 and 105 in the first direction (X-direction) may be configured to be relatively longer than a length a1 of the insulating layer 106 in the third direction (Z-direction) and a length a2 of the internal side walls 104B and 105B in the first direction (X-direction) disposed on an inner side, such that a short circuit defect between the coil 103 and the external electrodes 107 and 108 may be reduced. As the outermost side walls 104A and 105A are formed relatively long, inductance properties may deteriorate. Accordingly, in an embodiment, by adjusting the values of a1 and a2 together, conditions in which short circuit defects may be reduced and inductance properties may improve were derived through experiments.

In this case, b may be a length of the outermost side wall 104A or 105A in the first direction (X-direction) in a cross-section of the body 101 in the first direction-third direction (X-Z) including a central portion CL in the second direction. Also, a1 may be a length of the insulating layer 106 in a third direction (Z-direction) in a cross-section of the body 101 in the first direction-third direction (X-Z) including a central portion CL in the second direction (Y-direction). Also, when the insulating walls 104 and 105 include a plurality of internal side walls 104B and 105B, a2 may be an average of lengths of the plurality of internal side walls 104B and 105B in the first direction (X-direction).

As for the lengths a1, a2, and b, a1 and b may satisfy 2.11%<a1/b<18.01%. Lengths a1, a2, and b, and the length (thickness) of the support member may be measured using an optical microscope or scanning electron microscope (SEM). Other methods and/or tools appreciated by one of ordinary skill in the art, even if not described in the present disclosure, may also be used.

Table 1 below lists the results of measuring insulating properties and inductance properties according to the value of a1/b when the thickness of the support member was 40 μm, and Table 2 lists the results when the thickness of the support member was 20 μm. Insulating properties was determined through coil leakage defects, and when insulating properties was less than 20% of the required insulation resistance standard value (less than 20.10 mΩ in the case of the experimental model), the sample was marked as defective (X). As for inductance properties, when inductance properties was less than 20% of the required inductance Ls standard value (less than 0.264 μH in the case of the experimental model), the sample was marked as defective (X).

TABLE 1

| | | Coil | |
|---|---|---|---|
| | a1/b | insulating | Inductance |
| | (%) | properties | properties |
| 1 | 1.4 | x | ∘ |
| 2 | 2.11 | x | ∘ |
| 3 | 3.04 | ∘ | ∘ |
| 4 | 5.98 | ∘ | ∘ |
| 5 | 9.12 | ∘ | ∘ |
| 6 | 12.35 | ∘ | ∘ |
| 7 | 15.6 | ∘ | ∘ |
| 8 | 18.01 | ∘ | x |
| 9 | 20.42 | ∘ | x |

TABLE 2

| | | Coil | |
|---|---|---|---|
| | a1/b | insulating | Inductance |
| | (%) | properties | properties |
| 1 | 1.4 | x | ∘ |
| 2 | 2.11 | x | ∘ |
| 3 | 3.04 | ∘ | ∘ |
| 4 | 5.98 | ∘ | ∘ |
| 5 | 9.12 | ∘ | ∘ |
| 6 | 12.35 | ∘ | ∘ |
| 7 | 15.6 | ∘ | ∘ |
| 8 | 18.01 | ∘ | ∘ |
| 9 | 20.42 | ∘ | x |

According to the experimental results in Tables 1 and 2 above, when a1 and b satisfy the condition of 2.11%<a1/b<18.01%, normal levels of both insulating properties and inductance properties were obtained. When a1/b was less than 2.11%, it was confirmed that, as the thickness a1 of the insulating layer 106 decreased, the insulating properties decreased below the normal level. Also, it was confirmed 10 that, when a1/b was 18.01% or more, the volume of the insulating layer 106 increased excessively, such that inductance properties deteriorated.

The length a2 of the internal side walls 104B and 105B in the first direction (X-direction), disposed inwardly of the outermost side walls 104A and 105A in the insulating walls 104 and 105 in the first direction (X-direction), satisfied the condition of 1.54%<a2/b<11.3%. Table 3 below lists the results of measuring insulating properties and inductance properties according to the value of a2/b when the thickness of the support member was 40 μm, and Table 4 lists the results when the thickness of the support member was 20 μm.

TABLE 3

| | | Coil | |
|---|---|---|---|
| | a2/b | insulating | Inductance |
| | (%) | properties | properties |
| 1 | 1.54 | x | ∘ |
| 2 | 3.2 | ∘ | ∘ |
| 3 | 4.88 | ∘ | ∘ |
| 4 | 6.47 | ∘ | ∘ |
| 5 | 8.16 | ∘ | ∘ |
| 6 | 9.95 | ∘ | ∘ |
| 7 | 11.3 | ∘ | x |
| 8 | 12.87 | ∘ | x |
| 9 | 14.53 | ∘ | x |

TABLE 4

| | | Coil | |
|---|---|---|---|
| | a2/b | insulating | Inductance |
| | (%) | properties | properties |
| 1 | 1.54 | x | ∘ |
| 2 | 3.2 | ∘ | ∘ |
| 3 | 4.88 | ∘ | ∘ |
| 4 | 6.47 | ∘ | ∘ |
| 5 | 8.16 | ∘ | ∘ |
| 6 | 9.95 | ∘ | ∘ |
| 7 | 11.3 | ∘ | ∘ |
| 8 | 12.87 | ∘ | x |
| 9 | 14.53 | ∘ | x |

According to the experimental results in Tables 3 and 4, when a2 and b satisfied the condition of 1.54%<a2/b<11.3%, normal levels of both insulating properties and inductance properties were obtained. When a2/b was less than 1.54%, it was confirmed that, as the gap between coil turns excessively decreased, the insulating properties were lowered below the normal level. When a2/b was 11.3% or more, it was confirmed that, as the gap between turns of the coil was excessively widened, inductance properties deteriorated.

In addition to the conditions a1/b and a2/b, a1 and a2 may satisfy the condition a1>a2. Alternatively, a1 and a2 may satisfy the condition of a1≤a2. Also, referring to the experimental results, a lower limit of a1 may be a level at which insulating properties are not deteriorated, and may be 3 μm or more.

According to the aforementioned embodiments, a coil component which may improve insulating properties and inductance properties of a coil may be implemented.

While the embodiments have been illustrated and described above, it will be apparent to those skilled in the art that modifications and variations could be made without departing from the scope of the present disclosure as defined by the appended claims.

What is claimed is:

1. A coil component, comprising:
a body including a first surface and a second surface opposing each other in a first direction, a third surface and a fourth surface opposing each other in the second direction and disposed between the first surface and the second surface , and a fifth surface and a sixth surface opposing each other in the third direction and disposed between the first surface and the second surface;
a coil disposed in the body and including a plurality of turns;
an insulating wall surrounding a side surface of the coil and comprising an outermost side wall disposed on an outermost side of the insulating wall in the first direction;
an insulating layer covering the coil in the third direction; and
an external electrode connected to the coil,
wherein, when a length of the insulating layer in the third direction is defined as a1 and a length of the outermost side wall in the first direction is defined as b, 2.11%<a1/b<18.01% is satisfied.

2. The coil component of claim 1, wherein, when a length, in the first direction, of an internal side wall disposed inwardly of the outermost side wall is defined as a2, a2 and b satisfy 1.54%<a2/b<11.3%.

3. The coil component of claim 2, wherein a1 and a2 satisfy a1>a2.

4. The coil component of claim 2, wherein a1 and a2 satisfy a1≤a2.

5. The coil component of claim 2, wherein the insulating wall includes a plurality of internal side walls, and a2 is an average of lengths of the plurality of internal side walls in the first direction.

6. The coil component of claim 1, wherein a1 is 3 μm or more.

7. The coil component of claim 1, wherein b is the length of the outermost side wall in a cross-section of the body in the first direction and third direction, including a central portion in the second direction.

8. The coil component of claim 7, wherein a1 is a length of the insulating layer in a cross-section of the body in the first direction and third direction, including a central portion in the second direction.

9. The coil component of claim 1, further comprising:
a support member disposed in the body and supporting the coil.

10. The coil component of claim 9, wherein a length of the support member in the third direction is 5 μm or more and 40 μm or less.

11. The coil component of claim 9,
wherein the coil comprises a first coil disposed on one surface of the support member and having an end extending to the first surface of the body, and
wherein the insulating wall includes a first insulating wall disposed on the one surface of the support member and having a first outermost side wall extending to a second surface of the body.

12. The coil component of claim 11,
wherein the coil further comprises a second coil disposed on the other surface of the support member and having an end extending to a second surface of the body, and
wherein the insulating wall further includes a second insulating wall disposed on the other surface of the support member and having a second outermost side wall extending to the first surface of the body.

13. The coil component of claim 1, wherein the insulating layer covers the insulating wall in the third direction.

14. The coil component of claim 1, wherein the insulating wall includes a photosensitive insulating resin.

15. The coil component of claim 1, wherein an edge of the coil facing the insulating layer is flushed with an edge of the insulating wall facing the insulating layer.

16. The coil component of claim 9, wherein the support member includes a photosensitive insulating resin.

17. The coil component of claim 16, wherein a length of the support member in the third direction is 5 μm or more and 40 μm or less.

18. The coil component of claim 17, wherein, when a length, in the first direction, of an internal side wall disposed inwardly of the outermost side wall is defined as a2, a2 and b satisfy 1.54%<a2/b<11.3%.
